(19) United States
(12) Patent Application Publication
(10) Pub. No.: US 2014/0332777 A1
(43) Pub. Date: Nov. 13, 2014

(54) PHOSPHORESCENT HOST MATERIAL AND ORGANIC LIGHT-EMITTING DEVICE INCLUDING THE SAME

(71) Applicant: Electronics and Telecommunications Research Institute, Daejeon (KR)

(72) Inventors: Nam Sung CHO, Daejeon (KR); Joo Hyun HWANG, Seoul (KR); Jeong Ik LEE, Daejeon (KR)

(73) Assignee: Electronics and Telecommunications Research Institute, Daejeon (KR)

(21) Appl. No.: 14/259,730

(22) Filed: Apr. 23, 2014

(30) Foreign Application Priority Data
May 9, 2013 (KR) 10-2013-0052425
Nov. 27, 2013 (KR) 10-2013-0145338

(51) Int. Cl. H01L 51/00; H01L 51/50

(52) U.S. Cl. CPC H01L 51/0072; H01L 51/5012; H01L 51/0074
USPC 257/40; 548/440; 546/87

(57) ABSTRACT

Provided are a phosphorescent host material and an organic light-emitting device including the same. An emission material layer according to the inventive concept includes the phosphorescent host material and a phosphorescent dopant material. The phosphorescent host material has higher triplet energy than the phosphorescent dopant material. Thus, the light-emitting efficiency of the organic light-emitting device may be improved.

### CROSS-REFERENCE TO RELATED APPLICATIONS

This U.S. non-provisional patent application claims priority under 35 U.S.C. §119 of Korean Patent Application Nos. 10-2013-0052425, filed on May 9, 2013, and 10-2013-0145338, filed on Nov. 27, 2013, the entire contents of which are hereby incorporated by reference.

### BACKGROUND OF THE INVENTION

The present invention disclosed herein relates to a phosphorescent host material and an organic light-emitting device including the same.

An organic light-emitting device has properties such as an ultra light weight, rapid response time, driving at direct current and low voltage, etc., and is expected to be applied as a flat panel display of next generation. In addition, a light-emitting device in which organic light-emitting devices are disposed in a matrix type is known to be superior to a general liquid crystal display device when considering viewing angle and visibility.

An organic light-emitting diode (OLED) is a spontaneous light-emitting type device in which a light is emitted by exciting an organic light-emitting material. The OLED includes a substrate, a cathode, an anode and an emission material layer formed between the cathode and the anode. When a voltage is applied to the organic light-emitting device, electrons injected from the cathode and holes injected from the anode may recombine at the center of emission of the emission material layer and form molecular excitons. The molecular excitons emit light by emitting energy while coming back to a ground state. An excited state is known to include single excited state and triplet excited state, and the light emission is considered to be realized through any one of the excited states.

To improve the properties of the organic light-emitting device, improvement of a device structure or development of a material are performed. Recently, the use of a phosphorescent light-emitting material is found to be applicable in the organic light-emitting device as well as a fluorescent light-emitting material, and attracts much concern.

### SUMMARY OF THE INVENTION

The present invention provides a phosphorescent host material exhibiting blue color and has high triplet energy.

The present invention also provides an organic light-emitting device having improved light emitting efficiency.

Embodiments of the present invention provide organic light-emitting devices including a substrate, a first electrode on the substrate, an emission material layer provided on the first electrode and including a phosphorescent host material represented by following Formula 1, and a second electrode on the emission material layer.

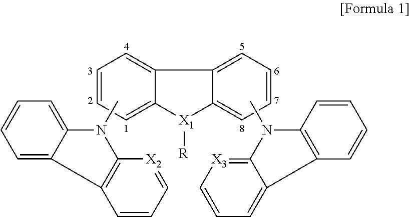

where X is any one selected from S, Se, N and O, R is any one selected from H, an aliphatic compound of C1-C10, an aromatic compound of C1-C10, alkyl silyl of C1-C10, alkoxy of C1-C10, aryl oxy of C1-C10, alkyl phosphoryl of C1-C10, aryl phosphoryl of C1-C10, alkyl sulfuryl of C1-C10, and aryl sulfuryl of C1-C10, a carbazole functional group including X₂ is substituted at position 1, 2 or 3, a carbazole group including X₃ is substituted at position 6, 7 or 8, X₁ is any one selected from S, O, N and C, X₂ is any one selected from S, O, N and C, and X₃ is any one selected from S, O, N and C.

In some embodiments, the phosphorescent host material may exhibit blue color.

In other embodiments, the phosphorescent host material may be any one selected from the compounds among following Formulae 4-1 to 4-4.

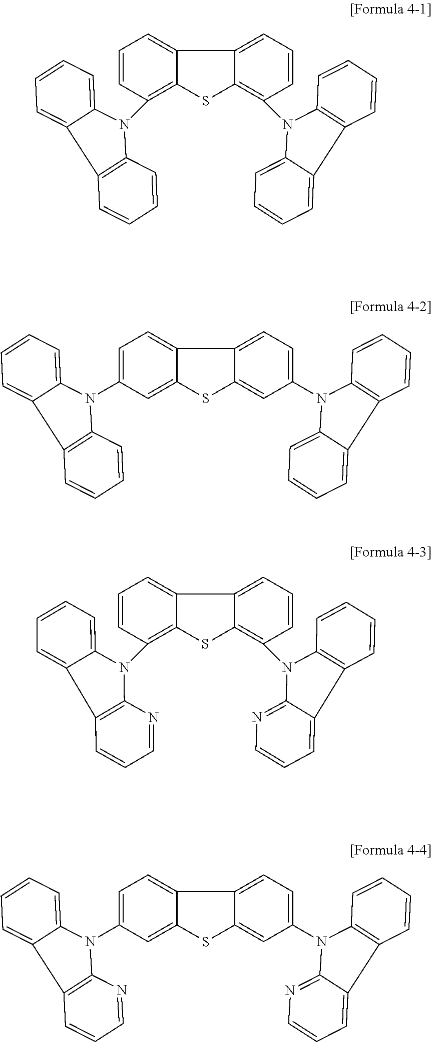 [SMILES: c1cc(-n2c3ccccc3c3ccccc32)c2sc3c(-n4c5ccccc5c5ccccc54)cccc3c2c1 ; c1ccc2c(c1)c1ccccc1n2-c1ccc2c(c1)sc1cc(-n3c4ccccc4c4ccccc43)ccc12 ; c1cc(-n2c3ccccc3c3cccnc32)c2sc3c(-n4c5ccccc5c5cccnc54)cccc3c2c1 ; c1ccc2c(c1)c1cccnc1n2-c1ccc2c(c1)sc1cc(-n3c4ccccc4c4cccnc43)ccc12]

In still other embodiments, the emission material layer may further include a phosphorescent dopant material, the phosphorescent dopant material may include a metal chelate complex, and the phosphorescent host material may have higher triplet energy than the phosphorescent dopant material.

In other embodiments of the present invention, organic light-emitting devices include a substrate, a first electrode and a second electrode separately disposed on the substrate, and an emission material layer provided between the first electrode and the second electrode and including a phosphorescent host material represented by following Formula 2.

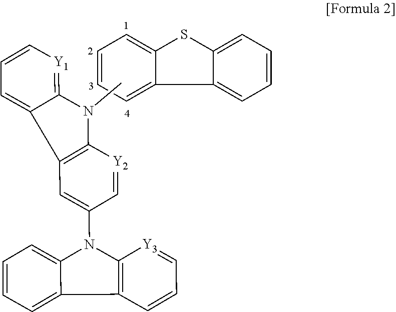

where each of Y1, Y2, and Y3 is independently any one selected from C and N, and substituent

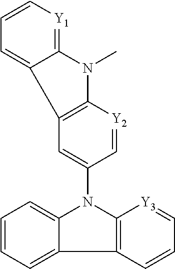

is substituted at position 1 or 3.

In some embodiments, the phosphorescent host material may be any one selected from the compounds among Formulae 5-1 to 5-6.

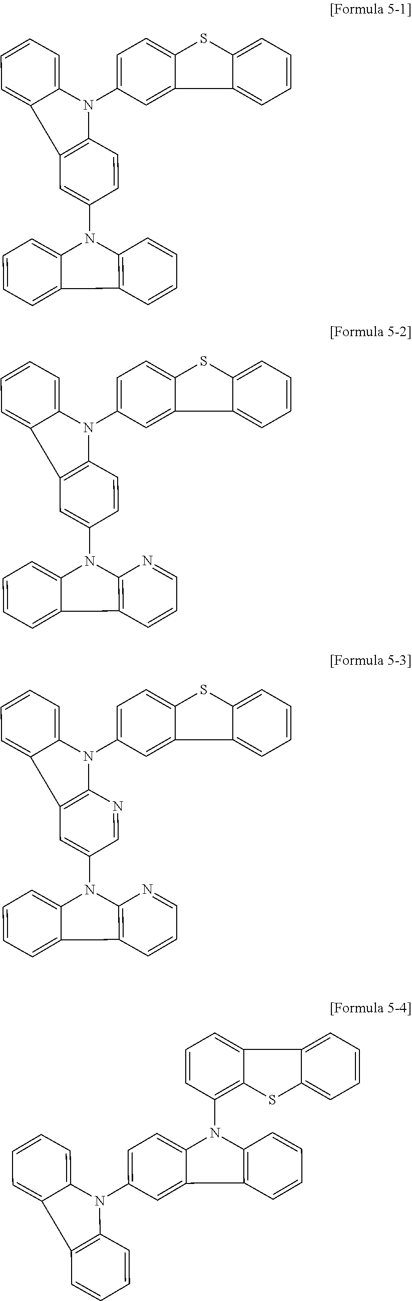 [SMILES: c1ccc2c(c1)sc1ccc(-n3c4ccccc4c4cc(-n5c6ccccc6c6ccccc65)ccc43)cc12 ; c1ccc2c(c1)sc1ccc(-n3c4ccccc4c4cc(-n5c6ccccc6c6cccnc65)ccc43)cc12 ; c1ccc2c(c1)sc1ccc(-n3c4ccccc4c4cc(-n5c6ccccc6c6cccnc65)cnc43)cc12 ; c1ccc2c(c1)sc1c(-n3c4ccccc4c4cc(-n5c6ccccc6c6ccccc65)ccc43)cccc12]

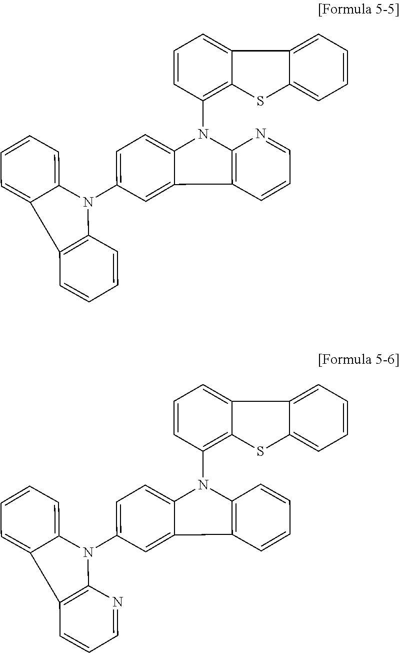 [SMILES: c1ccc2c(c1)sc1c(-n3c4ccc(-n5c6ccccc6c6ccccc65)cc4c4cccnc43)cccc12 ; c1ccc2c(c1)sc1c(-n3c4ccccc4c4cc(-n5c6ccccc6c6cccnc65)ccc43)cccc12]

In other embodiments, the emission material layer may further include a phosphorescent dopant material, the phosphorescent dopant material may include a platinum complex, an iridium complex, or a europium complex, and the phosphorescent host material may have higher triplet energy than the phosphorescent dopant material.

In still other embodiments of the present invention, phosphorescent host materials for an organic light-emitting device are represented by following Formula 1.

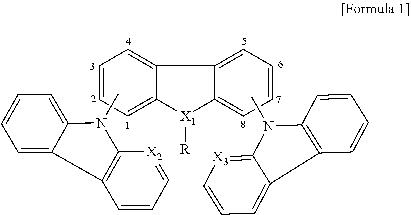

where X is any one selected from S, Se, N and O, R is any one selected from H, an aliphatic compound of C1-C10, an aromatic compound of C1-C10, alkyl silyl of C1-C10, alkoxy of C1-C10, aryl oxy of C1-C10, alkyl phosphoryl of C1-C10, aryl phosphoryl of C1-C10, alkyl sulfuryl of C1-C10, and aryl sulfuryl of C1-C10, a carbazole functional group including X₂ is substituted at position 1, 2 or 3, a carbazole group including X₃ is substituted at position 6, 7 or 8, X₁ is any one selected from S, O, N and C, X₂ is any one selected from S, O, N and C, and X₃ is any one selected from S, O, N and C.

In some embodiments, the phosphorescent host material may be selected from the compounds among Formulae 4-1 to 4-4.

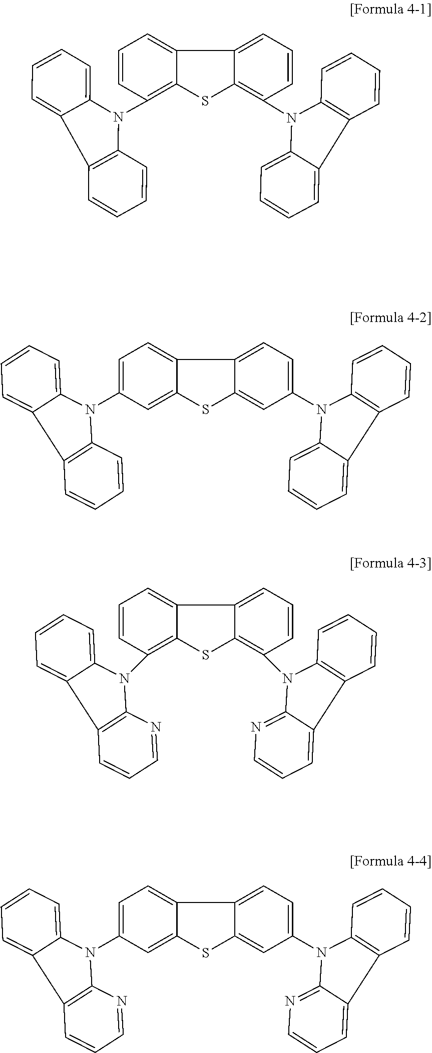 [SMILES: c1cc(-n2c3ccccc3c3ccccc32)c2sc3c(-n4c5ccccc5c5ccccc54)cccc3c2c1 ; c1ccc2c(c1)c1ccccc1n2-c1ccc2c(c1)sc1cc(-n3c4ccccc4c4ccccc43)ccc12 ; c1cc(-n2c3ccccc3c3cccnc32)c2sc3c(-n4c5ccccc5c5cccnc54)cccc3c2c1 ; c1ccc2c(c1)c1cccnc1n2-c1ccc2c(c1)sc1cc(-n3c4ccccc4c4cccnc43)ccc12]

### BRIEF DESCRIPTION OF THE DRAWINGS

The accompanying drawing is included to provide a further understanding of the present invention, and is incorporated in and constitutes a part of this specification. The drawing illustrates exemplary embodiments of the present invention and, together with the description, serves to explain principles of the present invention. In the drawing:

FIG. 1 is a cross-sectional view illustrating an organic light-emitting device according to an embodiment of the inventive concept.

### DETAILED DESCRIPTION OF PREFERRED EMBODIMENTS

The advantages and the features of the inventive concept, and methods for attaining them will be described in example embodiments below with reference to the accompanying drawings. The inventive concept may, however, be embodied in different forms and should not be construed as limited to the embodiments set forth herein. Rather, these embodiments are provided so that this description will be thorough and complete, and will fully convey the scope of the present inventive concept to those skilled in the art.

The terminology used herein is for the purpose of describing particular example embodiments only and is not intended to limit the present inventive concept. As used herein, the singular forms are intended to include the plural forms as well, unless the context clearly indicates otherwise. It will be further understood that the terms “comprises” and/or “comprising,” when used in this specification, specify the presence of stated features, steps, operations, and/or devices, but do not preclude the presence or addition of one or more other features, steps, operations, and/or devices thereof. It will also be understood that when a layer (or film) is referred to as being ‘on’ another layer or substrate, it can be directly on the other layer or substrate, or intervening layers may also be present.

It will also be understood that when a layer (or film) is referred to as being ‘on’ another layer (or film) or substrate, it can be directly on the other layer (or film) or substrate, or intervening layers (or films) may also be present.

It will be understood that, although the terms first, second, third etc. may be used herein to describe various regions, layers (or films), etc. these regions and layers should not be limited by these terms. These terms are only used to distinguish one region or layer (or film) from another region or layer (film). Thus, a first layer discussed below could be termed a second layer. Example embodiments embodied and described herein may include complementary example embodiments thereof. Like reference numerals refer to like elements throughout.

Unless otherwise defined, all terms used herein have the same meaning as commonly understood by one of ordinary skill in the art to which this inventive concept belongs.

Hereinafter, it will be described about an exemplary embodiment of the present invention in conjunction with the accompanying drawing.

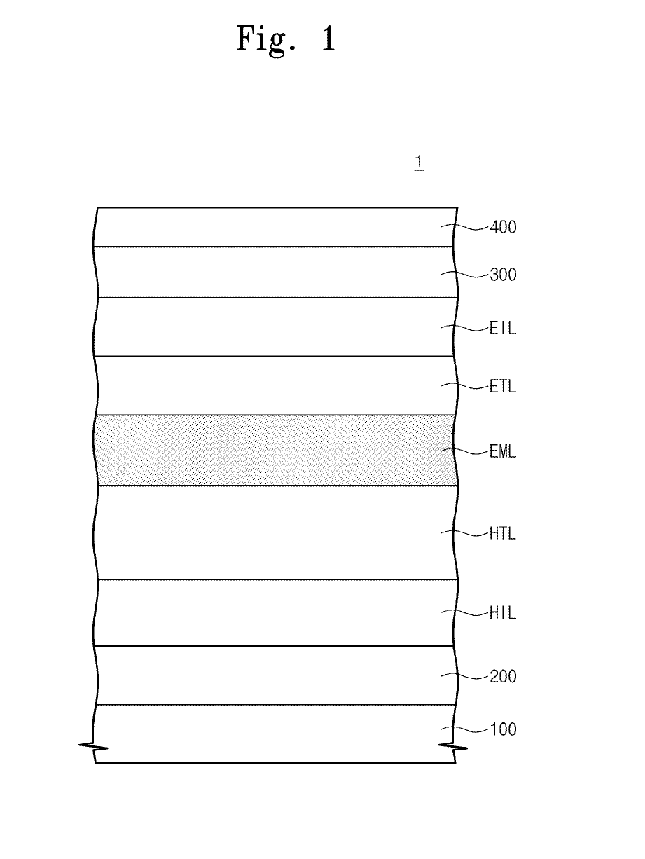

FIG. 1 is a cross-sectional view illustrating an organic light-emitting device according to an embodiment of the inventive concept.

Referring to FIG. 1, an organic light-emitting device 1 may include a substrate 100, a first electrode 200, a hole injection layer HIL, a hole transport layer HTL, an emission material layer EML, an electron transport layer ETL, an electron injection layer EIL, a second electrode 300, and a passivation layer 400.

The substrate 100 may be transparent. The substrate 100 may include at least one among glass, quartz or plastic.

The first electrode 200 may be provided on the substrate 100. The first electrode 200 may include a transparent conductive oxide such as indium-tin-oxide (ITO). Alternatively, the first electrode 200 may include a metal material. The first electrode 200 may function as an anode.

The hole transport layer HTL, the hole injection layer HIL, the emission material layer EML, the electron injection layer EIL, and the electron transport layer ETL may be stacked on the first electrode 200 one by one.

The emission material layer EML may include a phosphorescent host material and a phosphorescent dopant material. The phosphorescent host material may be represented by the following Formula 1 or Formula 2. The phosphorescent host material may exhibit blue color or green color.

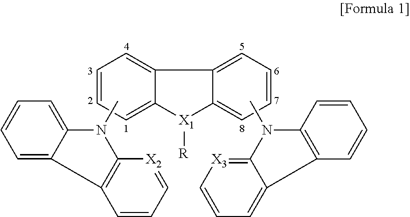

where X is any one selected from S, Se, N and O, R is any one selected from H, an aliphatic compound of C1-C10, an aromatic compound of C1-C10, alkyl silyl of C1-C10, alkoxy of C1-C10, aryl oxy of C1-C10, alkyl phosphoryl of C1-C10, aryl phosphoryl of C1-C10, alkyl sulfuryl of C1-C10, and aryl sulfuryl of C1-C10, a carbazole functional group including X₂ may be substituted at position 1, 2 or 3, a carbazole group including X₃ may be substituted at position 6, 7 or 8, X₁ is any one selected from S, O, N and C, X₂ is any one selected from S, O, N and C, and X₃ is any one selected from S, O, N and C.

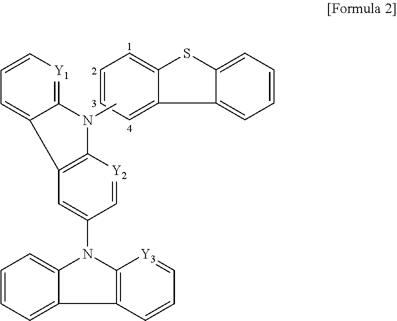

where each of Y1, Y2, and Y3 is independently any one selected from C and N. The substituent

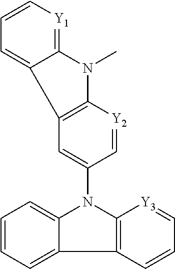

may be substituted at position 1 or 3.

The phosphorescent dopant material may be a complex including a metal central atom and an organic chelate combined therewith. The metal central atom of the phosphorescent dopant material may include iridium (Ir), platinum (Pt), or europium (Eu). For example, the phosphorescent dopant material may be iridium-bis(4,6-difluorophenylpyridinato-N,C2)-picolinate(Flrpic) represented by the following Formula 3.

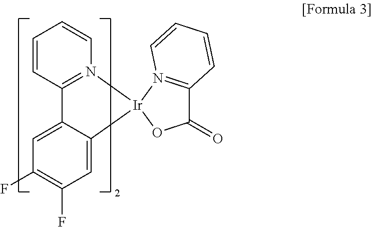

When an electric field is applied to the organic light-emitting device 1, holes may be produced at the first electrode 200, and electrons may be produced at the second electrode 300. The holes and the electrons may move to the emission material layer EML. The holes and the electrons may recombine at the phosphorescent host material of the emission material layer EML and may produce triplet excitons. Energy transition may occur from the triplet exciton of the phosphorescent host material to the triplet exciton of the phosphorescent dopant material. The triplet exciton of the phosphorescent dopant material may transit to a ground state and may emit light. When the phosphorescent host material has lower triplet energy than the phosphorescent dopant material, a reverse transition from the phosphorescent dopant material to the phosphorescent host material may be generated. The phosphorescent host material of the inventive concept may have a higher triplet energy level than the phosphorescent dopant material. For example, the phosphorescent host material may have the triplet energy level of about 2.6 eV or above, and more preferably, about 2.8 eV or above. Thus, electron transition from the triplet exciton of the phosphorescent host material to the triplet exciton of the phosphorescent dopant material may be efficiently generated. The light emitting efficiency of the emission material layer EML including the phosphorescent material of the present invention may be improved.

Particular examples of the phosphorescent host material represented by Formula 1 may include the following Formulae 4-1 to 4-4. In this case, the phosphorescent host material represented by the following Formulae 4-1 to 4-4 may have the energy level of the triplet state of about 3.0 eV. Thus, the light emitting efficiency of the organic light-emitting device 1 may be further improved.

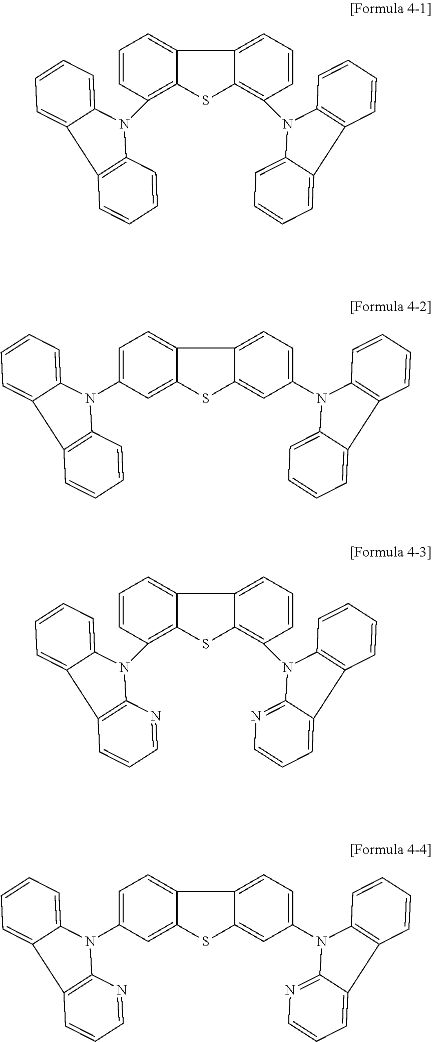 [SMILES: c1cc(-n2c3ccccc3c3ccccc32)c2sc3c(-n4c5ccccc5c5ccccc54)cccc3c2c1 ; c1ccc2c(c1)c1ccccc1n2-c1ccc2c(c1)sc1cc(-n3c4ccccc4c4ccccc43)ccc12 ; c1cc(-n2c3ccccc3c3cccnc32)c2sc3c(-n4c5ccccc5c5cccnc54)cccc3c2c1 ; c1ccc2c(c1)c1cccnc1n2-c1ccc2c(c1)sc1cc(-n3c4ccccc4c4cccnc43)ccc12]

Particular examples of the phosphorescent host material represented by Formula 2 may include the following Formulae 5-1 to 5-6. The phosphorescent host material represented by the following Formulae 5-1 to 5-6 may have the energy level of the triplet state of about 3.0 eV. Thus, the light emitting efficiency of the organic light-emitting device 1 may be further improved.

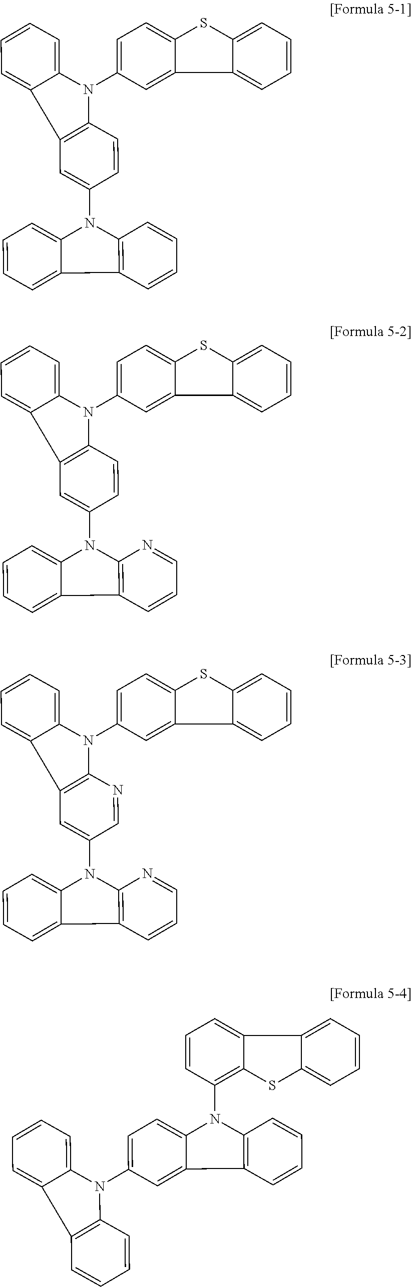 [SMILES: c1ccc2c(c1)sc1ccc(-n3c4ccccc4c4cc(-n5c6ccccc6c6ccccc65)ccc43)cc12 ; c1ccc2c(c1)sc1ccc(-n3c4ccccc4c4cc(-n5c6ccccc6c6cccnc65)ccc43)cc12 ; c1ccc2c(c1)sc1ccc(-n3c4ccccc4c4cc(-n5c6ccccc6c6cccnc65)cnc43)cc12 ; c1ccc2c(c1)sc1c(-n3c4ccccc4c4cc(-n5c6ccccc6c6ccccc65)ccc43)cccc12]

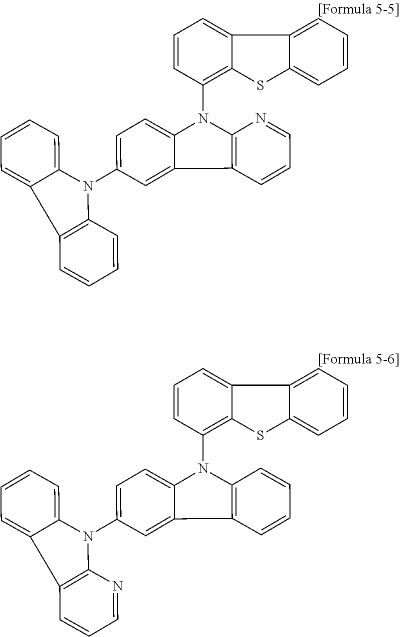 [SMILES: c1ccc2c(c1)sc1c(-n3c4ccc(-n5c6ccccc6c6ccccc65)cc4c4cccnc43)cccc12 ; c1ccc2c(c1)sc1c(-n3c4ccccc4c4cc(-n5c6ccccc6c6cccnc65)ccc43)cccc12]

The hole transport layer HTL may include 1,4,5,8,9,11-hexaazariphenylene-hexacarbonitrile (HATCN) represented by the following Formula 6. In an embodiment, the hole injection layer HIL may have the thickness of from about 30 nm to about 50 nm.

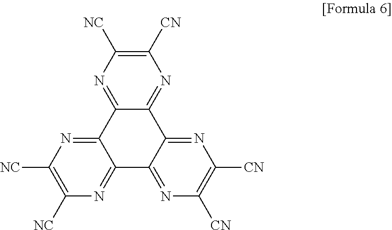 [SMILES: N#Cc1nc2c3nc(C#N)c(C#N)nc3c3nc(C#N)c(C#N)nc3c2nc1C#N]

The hole injection layer HIL may include 1,1-bis[4-[N,N′-di(p-tolyl)-amino]phenyl]cyclohexane (TAPC) represented by the following Formula 7-1, tris(4-carbazoyl-9-ylphenyl)amine (TCTA) represented by the following Formula 7-2, or lithium fluoride (LiF).

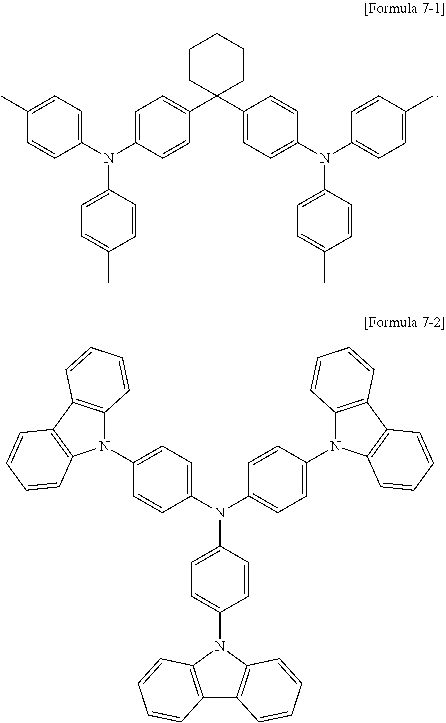

The second electrode 300 may be provided on the electron injection layer EIL. In an embodiment, the second electrode 300 may include a metal. In another embodiment, the second electrode 300 may include a transparent conductive oxide. The second electrode 300 may be a cathode.

The passivation layer 400 may be provided on the second electrode 300. In another embodiment, the passivation layer 400 may be omitted.

Hereinafter the preparation of the phosphorescent host material, the manufacture of an organic light-emitting device including the same, and the result obtained by evaluating the performance of the organic light-emitting device according to experimental examples will be explained.

### 1. Preparation of Phosphorescent Host Material

### Experimental Example 1

### Synthesis of Formula 4-1

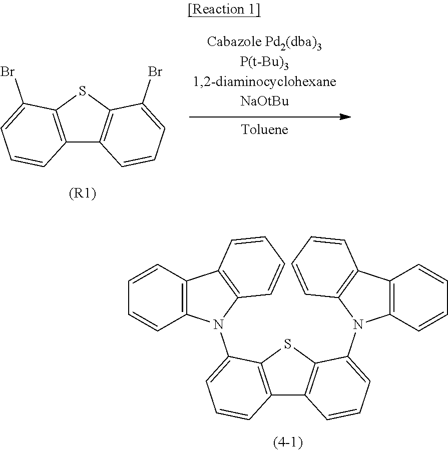

According to Reaction 1, a phosphorescent host material of Formula 4-1 was synthesized. Particularly, to reactant R1, carbazole, tris(dibenzylideneacetone)dipalladium (Pd₂(dba)₃), 1,2-diaminocyclohexane, tributyl phosphine (P(t-Butyl)₃), and sodium tert-butoxide (NaOtBu) were added. In this case, toluene was used as a solvent.

### Experimental Example 2-1

### Synthesis of Intermediate (C)

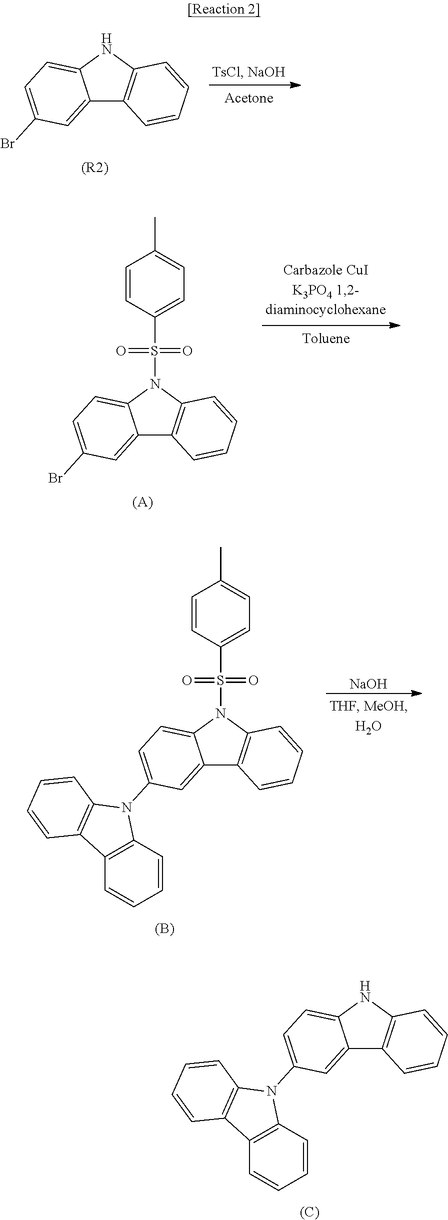

According to the above Reaction 2-1, intermediate (C) was synthesized. Particularly, in reactant R2, sodium hydroxide (NaOH) and toluenesulfonyl chloride (TsCl) ware added to prepare compound (A). In the compound (A), carbazole, copper iodide (CuI), potassium phosphate (K₃PO₄), and 1,2-diaminocyclohexane were added to synthesize compound (B). In the compound (B), sodium hydroxide (NaOH), tetrahydrofuran (THF), methanol, and water were added to synthesize the intermediate (C).

### Experimental Example 2-2

### Synthesis of Formula 5-1

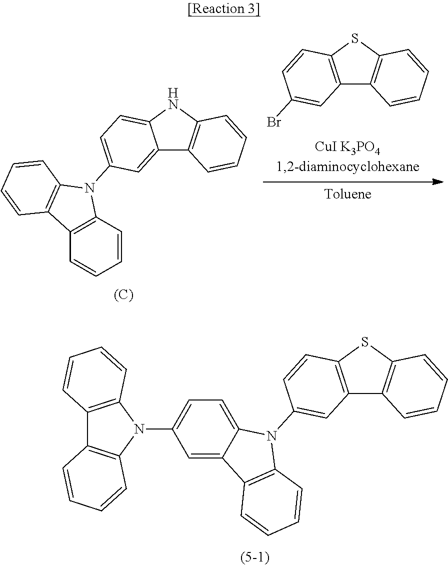

According to the above Reaction 3, a phosphorescent host material of Formula 5-1 was synthesized. In this case, the intermediate (C) synthesized in Reaction 2-1 was used.

### Experimental Example 3

### Synthesis of Formula 5-4

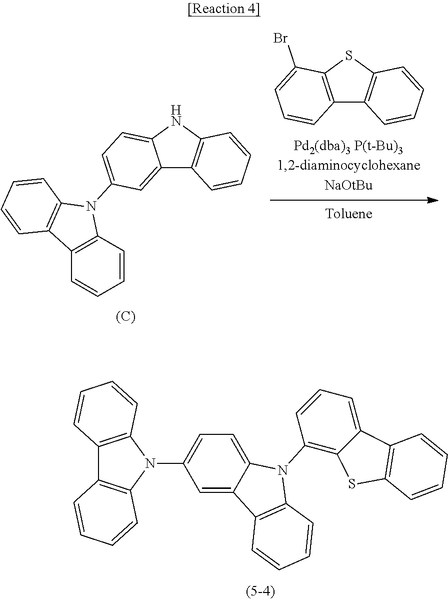

According to the above Reaction 4, a phosphorescent host material of Formula 5-4 was synthesized. In this case, the intermediate (C) synthesized in Reaction 2-1 was used.

### 2. Manufacture of Organic Light-Emitting Device

### Experimental Example 4

A transparent substrate was prepared. On the transparent substrate, ITO was deposited to form a first electrode. On the first electrode, HATCN represented by the above Formula 6 was coated to form a hole injection layer. On the hole injection layer, TAPC represented by the above Formula 7-1 was coated to form a hole transport layer. An emission material layer including the phosphorescent host material prepared in Experimental Example 1 was formed on the hole transport layer. In this case, the phosphorescent dopant material represented by the above Formula 3 was added. 1,3-bis[3,5-di(pyridine-3-yl)phenyl]benzene (BmPyPB) was coated on the emission material layer to form an electron injection layer. On the electron injection layer, a thin film including lithium fluoride (LiF) was formed. Thus, an electron transport layer was formed. Then, a second electrode was formed on the electron transport layer. The second electrode included aluminum.

### Experimental Example 5

An organic light-emitting device was manufactured by conducting the same procedure described in Experimental Example 4 except that the phosphorescent host material represented by Formula 5-1 synthesized in Experimental Example 2-2 was used.

### Experimental Example 6

An organic light-emitting device was manufactured by conducting the same procedure described in Experimental Example 4 except that the phosphorescent host material represented by Formula 5-4 synthesized in Experimental Example 3 was used.

### Comparative Example

An organic light-emitting device was manufactured by conducting the same procedure described in Experimental Example 4 except that a phosphorescent host material represented by the following Formula 8 was used.

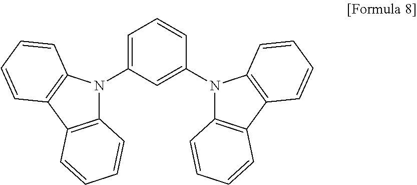 [SMILES: c1cc(-n2c3ccccc3c3ccccc32)cc(-n2c3ccccc3c3ccccc32)c1]

### 3. Evaluation of Properties of Organic Light-Emitting Device

The evaluation results of the organic light-emitting devices manufactured by Experimental Examples 4 to 6 according to the inventive concept and Comparative example are illustrated in the following Table 1.

TABLE 1

| | | Color | | External | | |
|---|---|---|---|---|---|---|
| | | coordinate | | quantum | Power | Luminance |
| | Voltage | value | | efficiency | efficiency | efficiency |
| | (V) | CIEx | CIEy | (%) | (lm/W) | (Cd/A) |
| Experimental | 4.7 | 0.14 | 0.31 | 17 | 21 | 29 |
| Example 4 | | | | | | |
| Experimental | 4.2 | 0.14 | 0.33 | 11 | 16 | 19 |
| Example 5 | | | | | | |
| Experimental | 4.6 | 0.14 | 0.33 | 13 | 16 | 22 |
| Example 6 | | | | | | |
| Comparative | 3.9 | 0.14 | 0.32 | 12 | 18 | 20 |
| Example | | | | | | |

From the measured results of the color coordinate values of the organic light-emitting device 1 manufactured by the experiment examples, it would be ensured that the phosphorescent host materials according to the experimental examples exhibit light blue color. In the phosphorescent host material represented by Formula 1, the synthesis of a phosphorescent host material in which a carbazole functional group including X₂ is substituted at position 1, 2 or 3, and a carbazole functional group including X₃ is substituted at position 6, 7 or 8 may not be easy. According to Experimental Example 1, the phosphorescent dopant material represented by Formula 1 may be synthesized. The phosphorescent host material according to the inventive concept may have higher triplet energy than the phosphorescent dopant material. Therefore, the performance (for example, external quantum efficiency, power efficiency, or luminance efficiency) of the organic light-emitting devices according to the experimental examples may be improved.

The organic light-emitting device according to the inventive concept may include a phosphorescent host material. The phosphorescent host material emits light having a wavelength corresponding to the blue color, and the organic light-emitting device may easily realize the blue color. The phosphorescent host material may have higher triplet energy than a phosphorescent dopant material. Thus, the light emitting efficiency of the organic light-emitting device including the phosphorescent host material may be improved.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An organic light-emitting device comprising:
a substrate;
a first electrode on the substrate;
an emission material layer provided on the first electrode and including a phosphorescent host material represented by following Formula 1; and
a second electrode on the emission material layer; 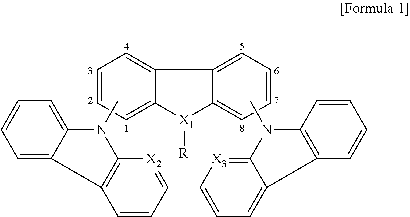
where X is any one selected from S, Se, N and O, R is any one selected from H, an aliphatic compound of C1-C10, an aromatic compound of C1-C10, alkyl silyl of C1-C10, alkoxy of C1-C10, aryl oxy of C1-C10, alkyl phosphoryl of C1-C10, aryl phosphoryl of C1-C10, alkyl sulfuryl of C1-C10, and aryl sulfuryl of C1-C10, a carbazole functional group including X₂ is substituted at position 1, 2 or 3, a carbazole group including X₃ is substituted at position 6, 7 or 8, X₁ is any one selected from S, O, N and C, X₂ is any one selected from S, O, N and C, and X₃ is any one selected from S, O, N and C.

2. The organic light-emitting device of claim 1, wherein the phosphorescent host material exhibit blue color.

3. The organic light-emitting device of claim 1, wherein the phosphorescent host material is any one selected from the compounds among following Formulae 4-1 to 4-4;

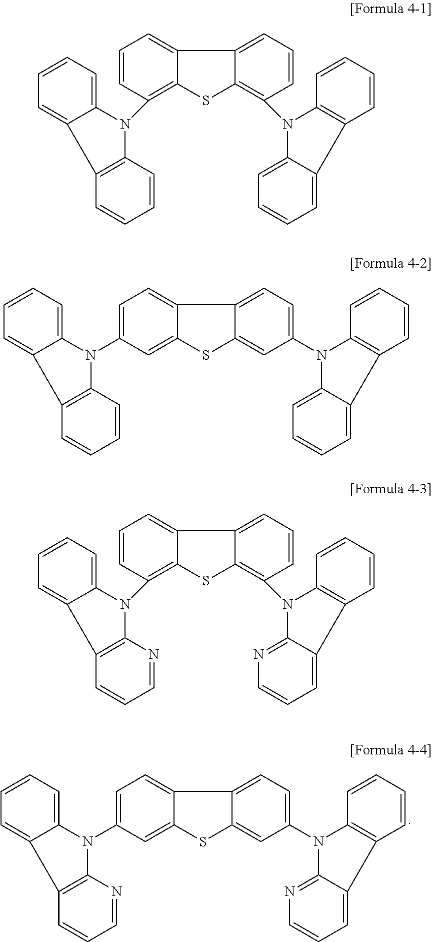 [SMILES: c1cc(-n2c3ccccc3c3ccccc32)c2sc3c(-n4c5ccccc5c5ccccc54)cccc3c2c1 ; c1ccc2c(c1)c1ccccc1n2-c1ccc2c(c1)sc1cc(-n3c4ccccc4c4ccccc43)ccc12 ; c1cc(-n2c3ccccc3c3cccnc32)c2sc3c(-n4c5ccccc5c5cccnc54)cccc3c2c1 ; c1ccc2c(c1)c1cccnc1n2-c1ccc2c(c1)sc1cc(-n3c4ccccc4c4cccnc43)ccc12]

4. The organic light-emitting device of claim 1,
wherein the emission material layer further comprises a phosphorescent dopant material, and the phosphorescent dopant material includes a metal chelate complex, and
wherein the phosphorescent host material has higher triplet energy than the phosphorescent dopant material.

5. An organic light-emitting device comprising:
a substrate;
a first electrode and a second electrode separately disposed on the substrate; and
an emission material layer provided between the first electrode and the second electrode and including a phosphorescent host material represented by following Formula 2; 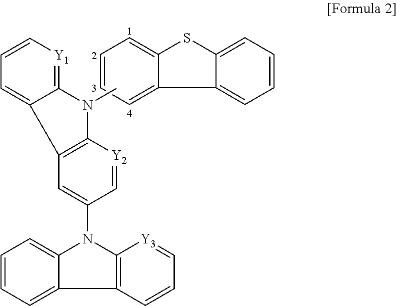
where each of Y1, Y2, and Y3 is independently any one selected from C and N, and substituent 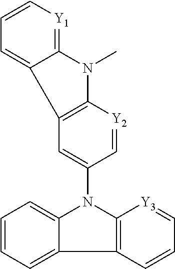
is substituted at position 1 or 3.

6. The organic light-emitting device of claim 5, wherein the phosphorescent host material is any one selected from the compounds among Formulae 5-1 to 5-6;

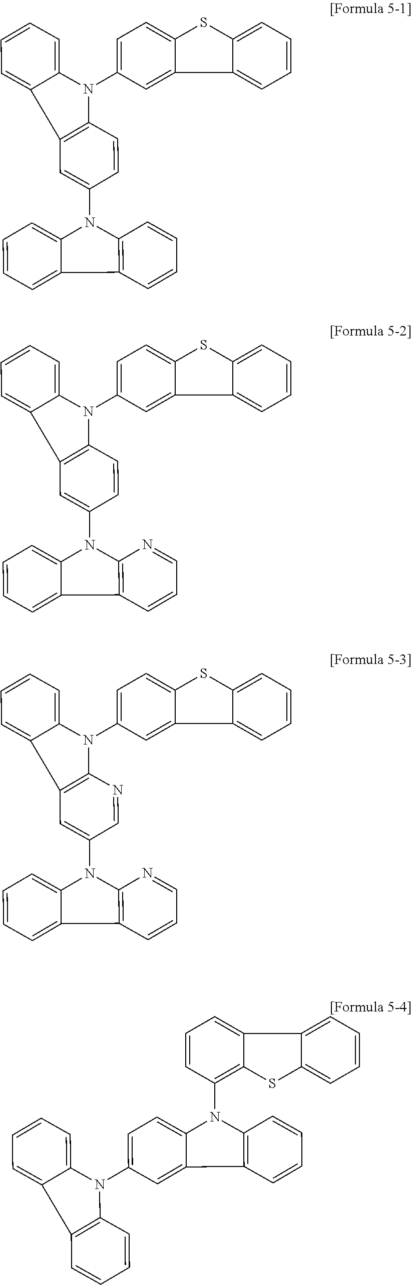 [SMILES: c1ccc2c(c1)sc1ccc(-n3c4ccccc4c4cc(-n5c6ccccc6c6ccccc65)ccc43)cc12 ; c1ccc2c(c1)sc1ccc(-n3c4ccccc4c4cc(-n5c6ccccc6c6cccnc65)ccc43)cc12 ; c1ccc2c(c1)sc1ccc(-n3c4ccccc4c4cc(-n5c6ccccc6c6cccnc65)cnc43)cc12 ; c1ccc2c(c1)sc1c(-n3c4ccccc4c4cc(-n5c6ccccc6c6ccccc65)ccc43)cccc12]

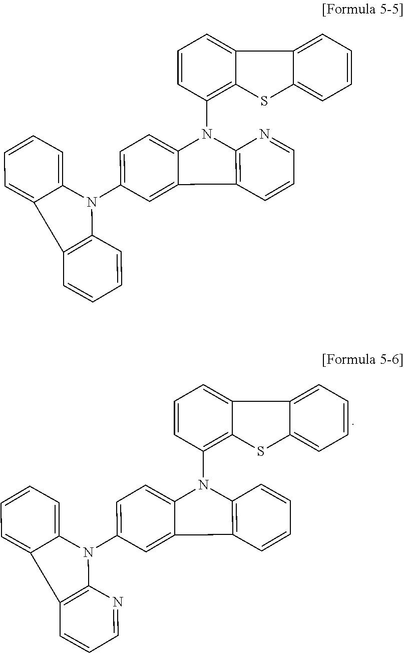 [SMILES: c1ccc2c(c1)sc1c(-n3c4ccc(-n5c6ccccc6c6ccccc65)cc4c4cccnc43)cccc12 ; c1ccc2c(c1)sc1c(-n3c4ccccc4c4cc(-n5c6ccccc6c6cccnc65)ccc43)cccc12]

7. The organic light-emitting device of claim 5,
wherein the emission material layer further includes a phosphorescent dopant material, and the phosphorescent dopant material includes a platinum complex, an iridium complex, or an europium complex, and
wherein the phosphorescent host material has higher triplet energy than the phosphorescent dopant material.

8. A phosphorescent host material for an organic light-emitting device represented by following Formula 1; 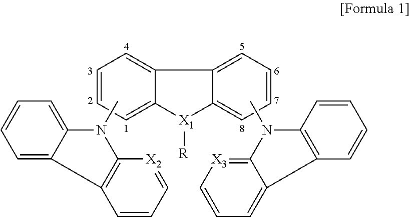
where X is any one selected from S, Se, N and O, R is any one selected from H, an aliphatic compound of C1-C10, an aromatic compound of C1-C10, alkyl silyl of C1-C10, alkoxy of C1-C10, aryl oxy of C1-C10, alkyl phosphoryl of C1-C10, aryl phosphoryl of C1-C10, alkyl sulfuryl of C1-C10, and aryl sulfuryl of C1-C10, a carbazole functional group including X₂ is substituted at position 1, 2 or 3, a carbazole group including X₃ is substituted at position 6, 7 or 8, X₁ is any one selected from S, O, N and C, X₂ is any one selected from S, O, N and C, and X₃ is any one selected from S, O, N and C.

9. The phosphorescent host material for an organic light-emitting device of claim 8, wherein the phosphorescent host material is selected from the compounds among Formulae 4-1 to 4-4; 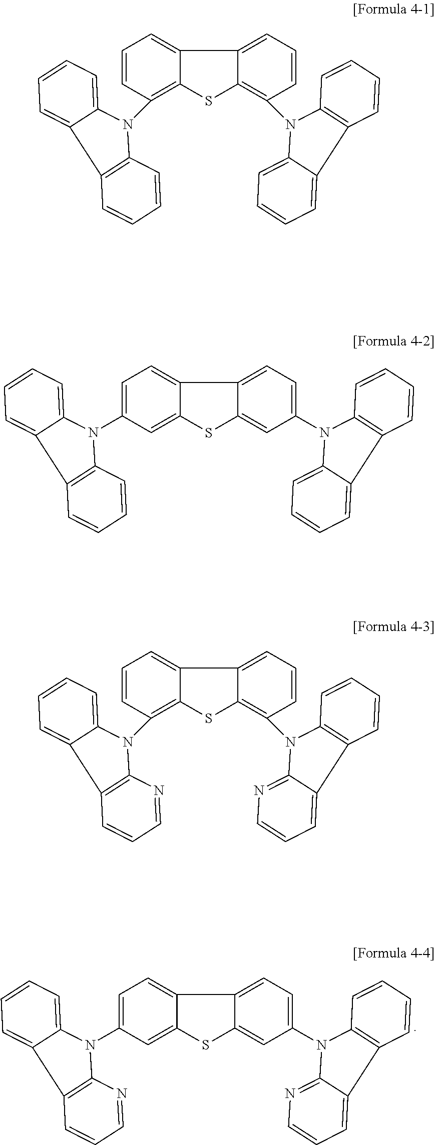 [SMILES: c1cc(-n2c3ccccc3c3ccccc32)c2sc3c(-n4c5ccccc5c5ccccc54)cccc3c2c1 ; c1ccc2c(c1)c1ccccc1n2-c1ccc2c(c1)sc1cc(-n3c4ccccc4c4ccccc43)ccc12 ; c1cc(-n2c3ccccc3c3cccnc32)c2sc3c(-n4c5ccccc5c5cccnc54)cccc3c2c1 ; c1ccc2c(c1)c1cccnc1n2-c1ccc2c(c1)sc1cc(-n3c4ccccc4c4cccnc43)ccc12]
